(19) United States
(12) Patent Application Publication
(10) Pub. No.: US 2015/0188022 A1
(43) Pub. Date: Jul. 2, 2015

(54) APPARATUS AND METHOD OF DRIVING PIEZOELECTRIC ACTUATOR

(71) Applicant: SAMSUNG ELECTRO-MECHANICS CO., LTD., Suwon-Si (KR)

(72) Inventors: Joo Yul Ko, Suwon-Si (KR); Chan Woo Park, Suwon-Si (KR)

(73) Assignee: SAMSUNG ELECTRO-MECHANICS CO., LTD., Suwon-Si (KR)

(21) Appl. No.: 14/246,908

(22) Filed: Apr. 7, 2014

(30) Foreign Application Priority Data
Dec. 30, 2013 (KR) 10-2013-0166895

(51) Int. Cl. H01L 41/04

(52) U.S. Cl. CPC H01L 41/042

(57) ABSTRACT

An apparatus for driving a piezoelectric actuator may include a waveform synthesizing unit outputting a digital signal by using a preset lookup table, a digital to analog converting unit outputting at least one of a symmetrical waveform or an asymmetrical waveform by converting the digital signal, and a controlling unit controlling an output of the asymmetrical waveform by controlling an output of the digital to analog converting unit in response to an external input.

### CROSS-REFERENCE TO RELATED APPLICATION

This application claims the benefit of Korean Patent Application No. 10-2013-0166895 filed on Dec. 30, 2013, with the Korean Intellectual Property Office, the disclosure of which is incorporated herein by reference.

### BACKGROUND

The present disclosure relates to an apparatus and a method of driving a piezoelectric actuator capable of protecting a piezoelectric device and having a high output, when necessary, by selectively using an asymmetrical driving signal and a symmetrical driving signal.

As an interest in user interfaces has increased and related technology has been developed, reactive technology for user input has become a key factor in designing user interfaces in a terminal.

An early reaction technology of providing simple vibrations in response to user inputs for providing intuitive data input confirmation to users has been used.

Recently, since providing reactions or vibrations to data input to users has emerged as an important factor in device design, the provision of vibrations to users with ever greater precision has become a major issue. In order to satisfy the above-mentioned issue, a technical transition from touch reaction technology according to the related art, based on a motor driving technology, to haptic technology, capable of providing various types of reactive feedback, has been conducted.

Haptic technology, which refers to an overall system transferring tactile feedback to a user, may transfer tactile feedback to a user by vibrating a vibration element to transfer physical impulses to the user. However, in order to provide haptic feedback to users for precise controlling, it is required to provide users with various types of reactive feedback.

Haptic technology is able to provide rich vibration patterns by using various vibrational frequencies. In order to satisfy demand for haptic technology, piezoelectric actuators formed of a ceramic material have been recently used. Piezoelectric actuators have faster response speeds, less noise, and higher resonance bandwidths than existing liner resonance actuators and vibration motors including magnets.

Since initial piezoelectric actuators have included a single piezoelectric layer, such devices have required a voltage exceeding 100V as a driving voltage for driving a piezoelectric device. Therefore, in the case of a mobile terminal such as a smart phone, or the like, a great deal of power may be consumed by the driving of the piezoelectric actuator including the single piezoelectric layer.

In order to solve the above-mentioned problem, a piezoelectric device including a plurality of piezoelectric layers has been used. However, such a piezoelectric device may have the limited driving voltage.

Particularly, in a case in which a driving voltage of a cathode, among the driving voltages, is strongly applied, it has an effect on a charge arrangement of a dielectric structure of the piezoelectric device, such that piezoelectric characteristics of the dielectric structure may be lost. Therefore, in a case of a piezoelectric device including a plurality of piezoelectric layers, an operating voltage thereof may be very limited. In addition, due to the limitations of such an operating voltage, output characteristics of the piezoelectric device may be deteriorated.

### SUMMARY

An exemplary embodiment in the present disclosure may provide an apparatus and a method of driving a piezoelectric actuator capable of protecting dielectric characteristics of a piezoelectric device and having a high output by selectively using an asymmetrical driving signal and a symmetrical driving signal to drive a piezoelectric device.

According to an exemplary embodiment in the present disclosure, an apparatus for driving a piezoelectric actuator may include: a waveform synthesizing unit outputting a digital signal by using a preset lookup table; a digital to analog converting unit outputting at least one of a symmetrical waveform or an asymmetrical waveform by converting the digital signal; and a controlling unit controlling an output of the asymmetrical waveform by controlling an output of the digital to analog converting unit in response to an external input.

The digital to analog converting unit may include: a non-weighted digital to analog converter outputting the symmetrical waveform corresponding to the digital signal; and a weighted digital to analog converter generating the asymmetrical waveform by reflecting a preset asymmetrical coefficient in at least a portion of the digital signal.

The non-weighted digital to analog converter may be a differential digital to analog converter generating a first analog signal corresponding to the digital signal and generating a second analog signal having a phase difference of 180° from the first analog signal.

A resistor connected to a least significant bit (LSB) of the weighted digital to analog converter may have a 1/n value of a resistance value of the non-weighted digital to analog converter, and a resistor connected to a most significant bit (MSB) thereof may have a value equal to n-times a resistance value of the non-weighted digital to analog converter, wherein n is a natural number.

The controlling unit may include a multiplexer receiving outputs from the non-weighted digital to analog converter and the weighted digital to analog converter and outputting either of the symmetrical waveform and the asymmetrical waveform.

The multiplexer may output either of the symmetrical waveform and the asymmetrical waveform to a negative terminal of a piezoelectric device.

The controlling unit may further include a controller controlling an operation of the multiplexer in response to a control signal input from the outside.

The controller may control the multiplexer to output the asymmetrical waveform when the control signal corresponds to an output of the asymmetrical driving signal.

According to an exemplary embodiment in the present disclosure, an apparatus for driving a piezoelectric actuator may include: a waveform synthesizing unit outputting first and second digital signals having a phase difference of 180° by using a preset lookup table; and a digital to analog converting unit outputting first and second analog signals corresponding to the first and second digital signals, respectively, wherein the waveform synthesizing unit generates the second digital signal as an asymmetrical waveform in response to a control signal input from the outside.

The asymmetrical waveform may be a waveform having a first polarity amplitude or a second polarity amplitude having a different magnitude.

The waveform synthesizing unit may generate the first digital signal by using a plurality of digital values included in a preset lookup table and generate the second digital signal by applying a preset asymmetrical coefficient to at least a portion of the plurality of digital values.

The waveform synthesizing unit may only apply the asymmetrical coefficient to the digital value corresponding to the first polarity of the second digital signal.

The apparatus may further include an amplifying unit amplifying the first and second analog signals to respectively provide the amplified first and second analog signals to both terminals of a piezoelectric device.

According to an exemplary embodiment in the present disclosure, a method of driving a piezoelectric actuator may include: determining a request for asymmetrical driving by receiving an external input signal; when the request for the asymmetrical driving is determined, generating a symmetrical first digital signal and an asymmetrical second digital signal; and generating first and second analog signals corresponding to the first and second digital signals, respectively.

The generating of the first and second digital signals may include: generating the first digital signal having a first polarity amplitude and a second polarity amplitude having the same magnitude as each other by using a plurality of digital values included in a preset lookup table; and generating the second digital signal having a first polarity amplitude and a second polarity amplitude having a different magnitude by applying a preset asymmetrical coefficient to at a least a portion of the plurality of digital values.

The generating of the second digital signal may include only applying the asymmetrical coefficient to the digital value corresponding to the first polarity of the second digital signal.

The method may further include amplifying the first and second analog signals to respectively provide the amplified first and second analog signals to both terminals of a piezoelectric device.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a graph illustrating a general example of a pair of waveforms applied to both terminals of a piezoelectric device;

FIG. 2 is a graph illustrating a driving signal applied to the piezoelectric device by the pair of waveforms of FIG. 1;

FIG. 3 is a graph illustrating an example of a displacement according to an operating voltage of a driving signal of the piezoelectric device;

FIG. 4 is a block diagram illustrating an apparatus for driving a piezoelectric actuator according to an exemplary embodiment of the present disclosure;

FIG. 5 is a graph illustrating an example of a signal output from a waveform synthesizing unit of FIG. 4;

FIG. 6 illustrates a digital to analog converter according to an exemplary embodiment of the present disclosure;

FIG. 7 illustrates a weighted digital to analog converter according to an exemplary embodiment of the present disclosure;

FIG. 8 is a graph illustrating an asymmetrical analog signal and a symmetrical analog signal which are input to a multiplexer;

FIG. 9 is a graph illustrating a driving signal applied to the piezoelectric device by the pair of analog signals of FIG. 8;

FIG. 10 is a block diagram illustrating an apparatus for driving a piezoelectric actuator according to another exemplary embodiment of the present disclosure;

FIG. 11 is a graph illustrating an example of a digital signal output from a waveform synthesizing unit of FIG. 10; and

FIG. 12 is a flow chart describing a method of driving a piezoelectric actuator according to an exemplary embodiment of the present disclosure.

### DETAILED DESCRIPTION

Hereinafter, exemplary embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

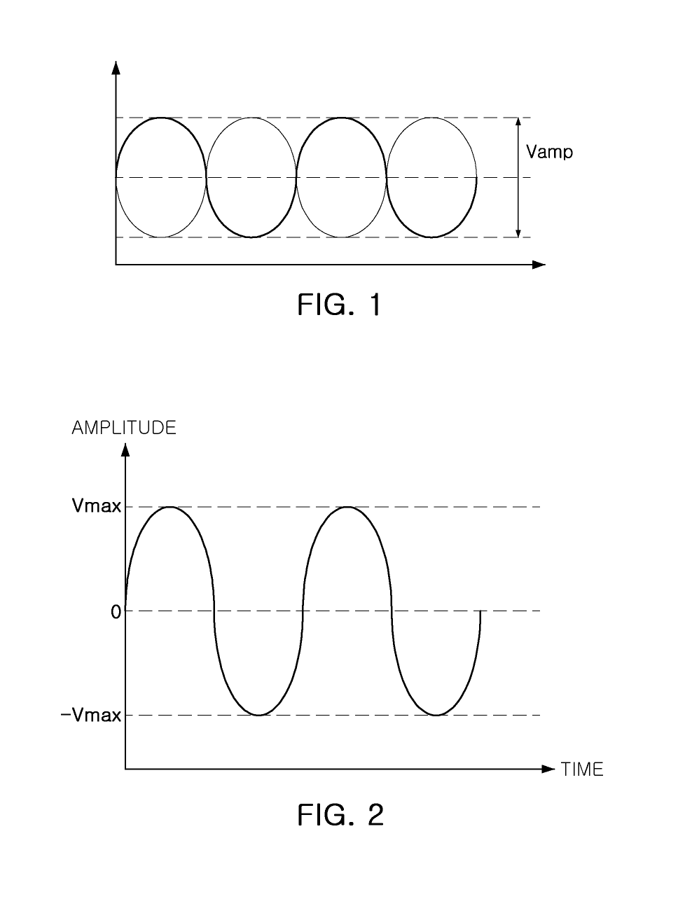

FIG. 1 is a graph illustrating a general example of a pair of waveforms applied to both terminals of a piezoelectric device.

The graph of FIG. 1 illustrates a pair of waveforms having a phase difference of 180°. The pair of waveforms may be respectively input to both terminals of a piezoelectric device. For example, a first waveform indicated by a thick line may be input to an anode terminal of the piezoelectric device and a second waveform indicated by a thin line may be input to a cathode terminal of the piezoelectric device.

In addition, as illustrated in FIG. 1, the general waveform may have characteristics symmetrical with each other. For example, the waveforms illustrated may have a negative amplitude and a positive amplitude having the same magnitude as each other.

FIG. 2 is a graph illustrating a driving signal applied to the piezoelectric device by the pair of waveforms of FIG. 1. In detail, FIG. 2 illustrates the driving signal obtained by subtracting the second waveform of FIG. 1 from the first waveform thereof.

In addition, the waveform shown in FIG. 2 may be the driving signal input to the piezoelectric device. For example, the driving signal shown in FIG. 1 respectively illustrates the waveforms input to both terminals of the piezoelectric device and FIG. 2 illustrates the driving signal applied to the piezoelectric device by the waveforms applied to both terminals thereof.

Similar to those described above, it may be appreciated that the driving signal applied to the piezoelectric device also has a symmetrical form.

As described above with reference to FIGS. 1 and 2, in order to generally drive the piezoelectric device, the symmetrical driving signal may be used. However, in this case, a magnitude of the applied driving signal, for example, a voltage value needs to have a limited magnitude.

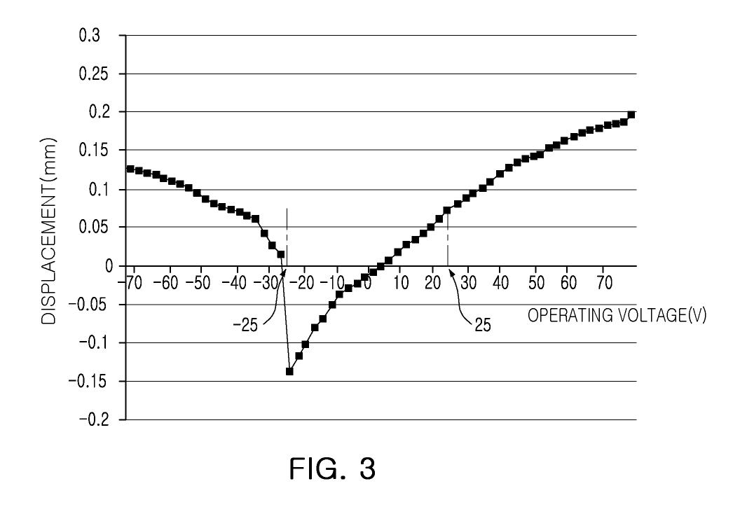

FIG. 3 is a graph illustrating an example of a displacement according to an operating voltage of a driving signal of the piezoelectric device. Hereinafter, the limitation of the magnitude of the voltage value will be described with reference to FIG. 3.

As shown in FIG. 3, in the case in which the driving voltage has a positive value, it may be appreciated that the displacement is increased while being in proportion to a magnitude of the applied driving voltage. On the other hand, in the case in which the driving voltage has a negative value, it may be appreciated that the displacement of the piezoelectric device is sharply changed from negative (−) to positive (+) when a predetermined threshold value, for example, a voltage below −25V is applied in an example illustrated. This phenomenon is caused because polarization of the piezoelectric device is relaxed as a voltage having reverse polarity is strongly applied to the piezoelectric device.

For example, in the case in which the driving voltage in a negative direction is strongly applied to the piezoelectric device, since charges polarized in the piezoelectric device are relaxed, the piezoelectric device loses piezoelectric characteristics.

Therefore, only a negative threshold value of the driving voltage, for example, a voltage which is larger than −25V in the example illustrated, needs to be used as the driving voltage. Therefore, the positive threshold value of the driving voltage is also limited to +25V. Here, the positive magnitude and the negative magnitude of the driving voltage need to correspond to each other as described with reference with FIGS. 1 and 2.

As a result, the driving voltage of the piezoelectric device is limited to a range of −25V to +25V. This driving voltage may be varied depending on laminated times of the piezoelectric device. However, since the negative threshold value of the driving voltage relaxing the polarization is increased as the laminated times of the piezoelectric device is increased, the range of the driving voltage is further decreased.

Therefore, a portion of a positive range of a piezoelectric driving voltage may be used due to the problem described above. For example, in a case of an example in FIG. 3, although the piezoelectric device has piezoelectric characteristics even at the voltage of +25V or more, only a voltage up to +25V may be used to correspond to the negative threshold value of the driving voltage in which polarization is relaxed. Due to the above-mentioned limitation, an absolute range of a voltage for driving a piezoelectric actuator relatively is reduced, such that the piezoelectric device may also have a limited output.

In order to solve the problem described above, hereinafter, a technology for driving a piezoelectric actuator according to an exemplary embodiment of the present disclosure will be described together with various exemplary embodiments of the present disclosure.

The technology for driving the piezoelectric actuator according to an exemplary embodiment of the present disclosure described below may maintain characteristics of the piezoelectric device and provide a higher output by applying an asymmetrical waveform to the piezoelectric device as a driving signal to thereby satisfy the negative threshold value of the piezoelectric device described above.

In addition, the technology for driving the piezoelectric actuator according to an exemplary embodiment of the present disclosure may selectively use an asymmetrical driving signal and a symmetrical driving signal depending on a request from the outside to thereby provide a function of adjusting the output.

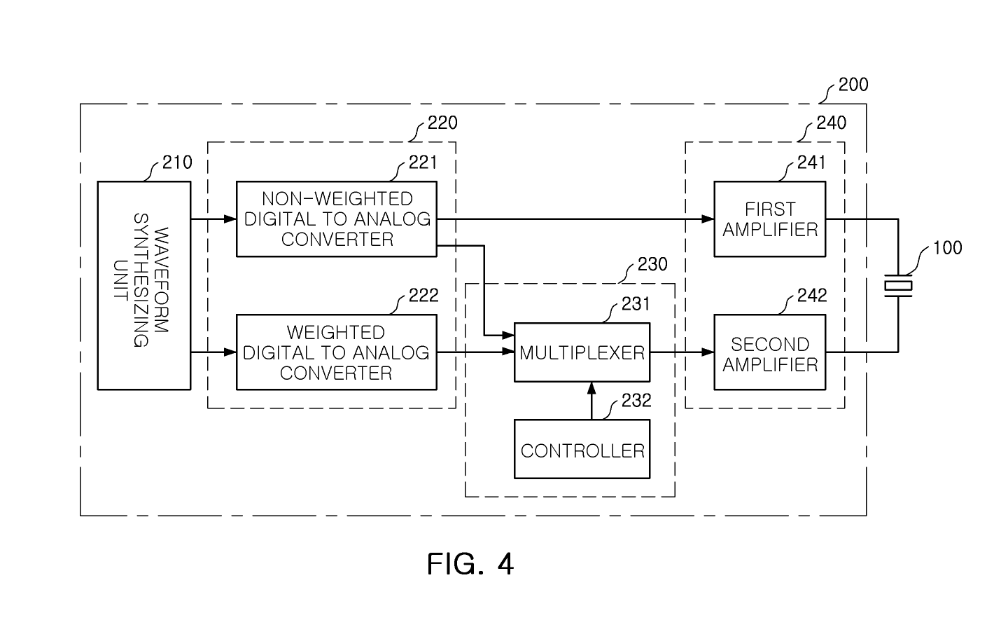

Hereinafter, an apparatus for driving a piezoelectric actuator according to an exemplary embodiment of the present disclosure will be described with reference to FIGS. 4 through 7.

FIG. 4 is a block diagram illustrating an apparatus for driving a piezoelectric actuator according to an exemplary embodiment of the present disclosure.

The apparatus for driving the piezoelectric actuator 200 may drive a piezoelectric device 100 by applying a predetermined driving signal to the piezoelectric device 100. For example, the apparatus 200 for driving the piezoelectric actuator may apply the driving signal by providing a pair of waveforms to both terminals of the piezoelectric device 100. Here, the driving signal applied to the piezoelectric device 100 may be a symmetrical signal as well as an asymmetrical signal.

According to an exemplary embodiment of the present disclosure, the apparatus 200 for driving the piezoelectric actuator may include a waveform synthesizing unit 210, a digital to analog converting unit 220, a controlling unit 230 and an amplifying unit 240.

The waveform synthesizing unit 210 may output a predetermined digital value (hereinafter, referred to as a digital signal) for generating the driving signal.

According to an exemplary embodiment of the present disclosure, the waveform synthesizing unit 210 may select and output at least a portion of the digital values included in a preset lookup table. According to another exemplary embodiment of the present disclosure, the waveform synthesizing unit 210 may output the digital value by using a preset function.

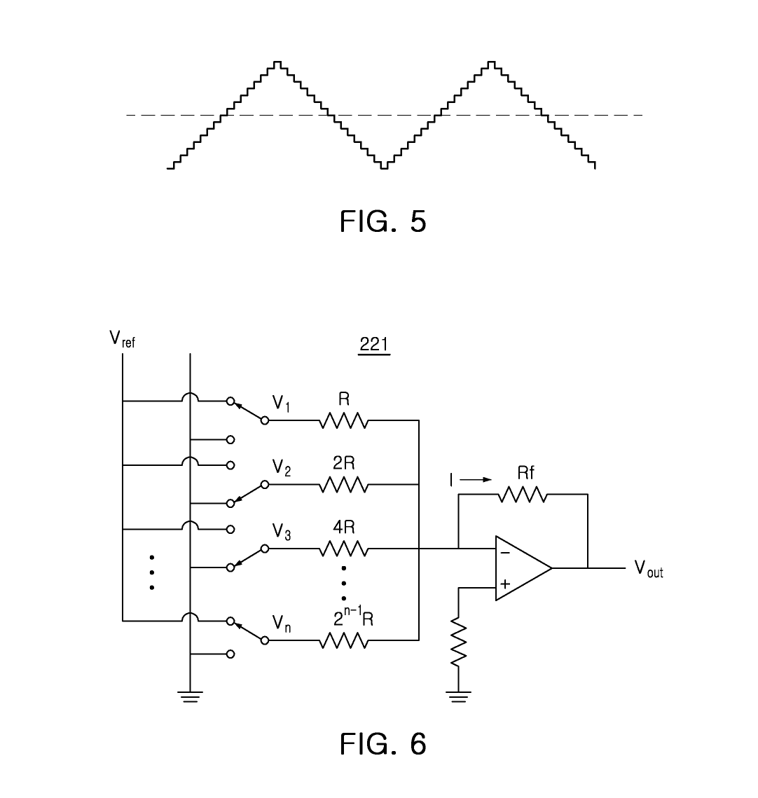

As illustrated in FIG. 5, the digital signal output from the waveform synthesizing unit 210 may be a symmetrical digital signal having a first polarity displacement and a second polarity displacement corresponding to each other. The waveform synthesizing unit 210 may provide the digital signal generated described above to the digital to analog converting unit 220.

Referring back to FIG. 4, the digital to analog converting unit 220 may output at least one of a symmetrical waveform or an asymmetrical waveform by converting the digital signal.

According to an exemplary embodiment of the present disclosure, the digital to analog converting unit 220 may include a non-weighted digital to analog converter 221 and a weighted digital to analog converter 222. Each of the non-weighted digital to analog converter 221 and the weighted digital to analog converter 222 may receive the digital signal output from the waveform synthesizing unit 210 and convert the received digital signal into an analog signal.

The non-weighted digital to analog converter 221 may output the symmetrical waveform corresponding to the digital signal.

According to an exemplary embodiment of the present disclosure, the non-weighted digital to analog converter 221 may be a differential digital to analog converter generating a first analog signal corresponding to the digital signal and a second analog signal having a phase difference of 180° from the first analog signal.

The weighted digital to analog converter 222 may generate the asymmetrical waveform by reflecting a preset asymmetrical coefficient in at least a portion of the digital signal.

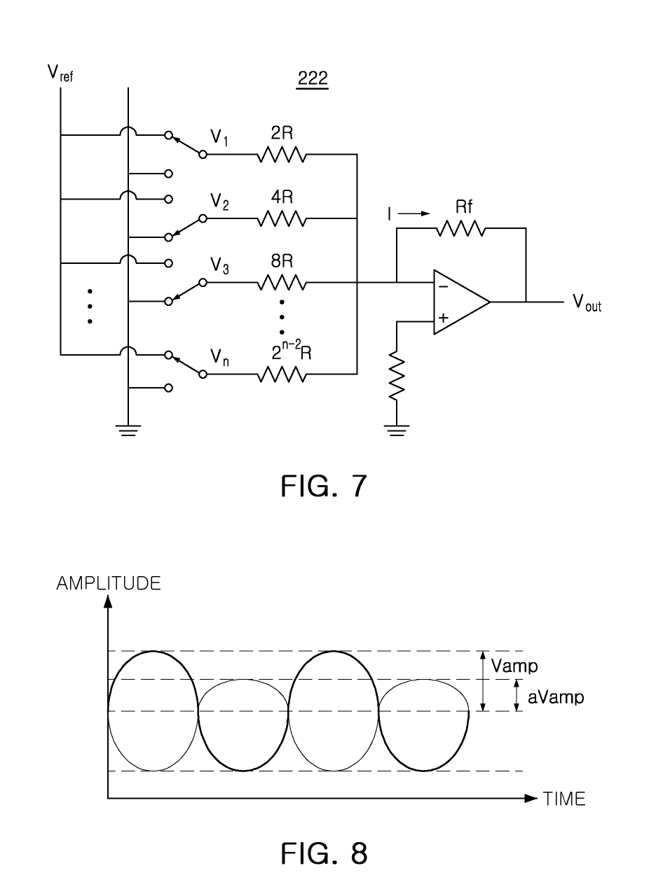

FIG. 6 illustrates a non-weighted digital to analog converter 221 according to an exemplary embodiment of the present disclosure and FIG. 7 illustrates a weighted digital to analog converter 222 according to an exemplary embodiment of the present disclosure.

Referring to FIGS. 6 and 7, the non-weighted digital to analog converter 221 may convert the received digital signal into an analog signal and output the converted analog signal.

The non-weighted digital to analog converter 221 may perform a switching operation in response to the received digital signal. The switching operation as mentioned above may select a resistance value, whereby a magnitude of the output analog signal may be changed. The output of the non-weighted digital to analog converter 221 may be represented by the following Equation 1.

$${V}_{out} = - {IR}_{f} = - {R}_{f} ( \frac{{V}_{1}}{R} + \frac{{V}_{2}}{2 R} + \frac{{V}_{3}}{4 R} + … \frac{{V}_{n}}{{2}^{n - 1} R} ) \qquad [ Equation 1 ]$$

Meanwhile, the weighted digital to analog converter 222 may output an asymmetrical analog signal by applying an asymmetrical coefficient to the received digital signal. The above-mentioned asymmetrical coefficient may be reflected in a resistor of the weighted digital to analog converter 222.

Referring to an example of FIG. 7, the weighted digital to analog converter 222 may use weighted resistors. For example, comparing to the resistors of the non-weighted digital to analog converter 221 of FIG. 6, it may be appreciated that a resistor connected to a least significant bit (LSB) of the weighted digital to analog converter 222 has a 1/n value of a resistance value of the non-weighted digital to analog converter 221, and a resistor connected to a most significant bit (MSB) has a value equal to n-times a resistance value of the non-weighted digital to analog converter 221. Here, n is a natural number, but is two in the example illustrated. This may be represented by the following Equation 2.

$${V}_{out} = - {IR}_{f} = - {R}_{f} ( \frac{{V}_{1}}{2 R} + \frac{{V}_{2}}{4 R} + \frac{{V}_{3}}{8 R} + … \frac{{V}_{n}}{{2}^{n - 2} R} ) \qquad [ Equation 2 ]$$

Referring back to FIG. 4, the controlling unit 230 may control the output of the digital to analog converting unit 220 in response to an external input to thereby control the output of the asymmetrical waveform.

The controlling unit 230 may include a multiplexer 231. The multiplexer 231 may receive the outputs of the non-weighted digital to analog converter 221 and the weighted digital to analog converter 222 and may output either of the symmetrical waveform and the asymmetrical waveform.

The multiplexer 231 may output either of the symmetrical waveform and the asymmetrical waveform to a negative terminal of the piezoelectric device. According to an exemplary embodiment of the present disclosure, the output of the multiplexer 231 may be amplified by a second amplifying unit 242 to thereby be provided to the negative terminal of the piezoelectric device.

The controlling unit 230 may further include a controller 232. The controller 232 may control an operation of the multiplexer 231 in response to a control signal input from the outside.

According to an exemplary embodiment of the present disclosure, in the case in which the control signal corresponds to the output of the asymmetrical driving signal, the controller 232 may control the multiplexer to output the asymmetrical waveform.

FIG. 8 is a graph illustrating an asymmetrical analog signal and a symmetrical analog signal which are input to a multiplexer. As illustrated in FIG. 8, an asymmetry analog signal and a symmetrical analog signal having a phase difference of 180° are illustrated. In addition, it may be appreciated that an asymmetry coefficient a is applied to a value having a positive polarity of the asymmetry analog signal illustrated by a thin line. For example, it may be appreciated that the asymmetrical analog signal is an asymmetrical signal because a positive polarity value of the asymmetrical analog signal has a value lower than a negative polarity value thereof.

The symmetrical analog signal may be applied to the positive terminal of the piezoelectric device and the asymmetrical analog signal may be applied to the negative terminal of the piezoelectric device.

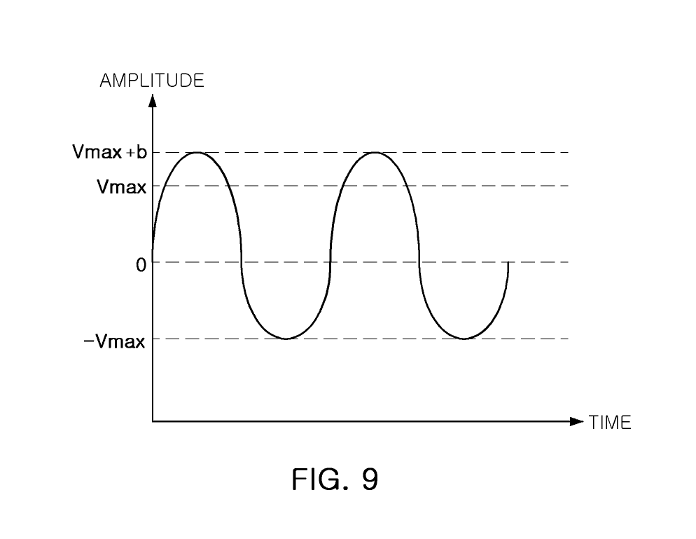

FIG. 9 is a graph illustrating a driving signal applied to the piezoelectric device by the pair of analog signals of FIG. 8. For example, in the case in which the pair of analog signals of FIG. 8 are respectively input to the positive terminal and the negative terminal of the piezoelectric device, the piezoelectric device may be applied with the driving signal of FIG. 9.

In detail, when the asymmetrical analog signal is subtracted from the symmetrical analog signal of FIG. 8, then the driving signal of FIG. 9 may be derived.

It may be appreciated that the driving signal illustrated in FIG. 9 has a positive polarity amplitude larger than a negative polarity amplitude. As described above with reference with FIG. 4, the piezoelectric device 100 has characteristics that it has the threshold value which is present in the negative voltage, but does not have a separate threshold value for the positive polarity. Therefore, according to an exemplary embodiment of the present disclosure, the asymmetrical signal as illustrated in FIG. 8, for example, the signal satisfying the negative threshold value and having the higher voltage for the positive polarity is applied, whereby a stronger driving signal may be applied in a range in which the piezoelectric device 100 does not lose characteristics thereof.

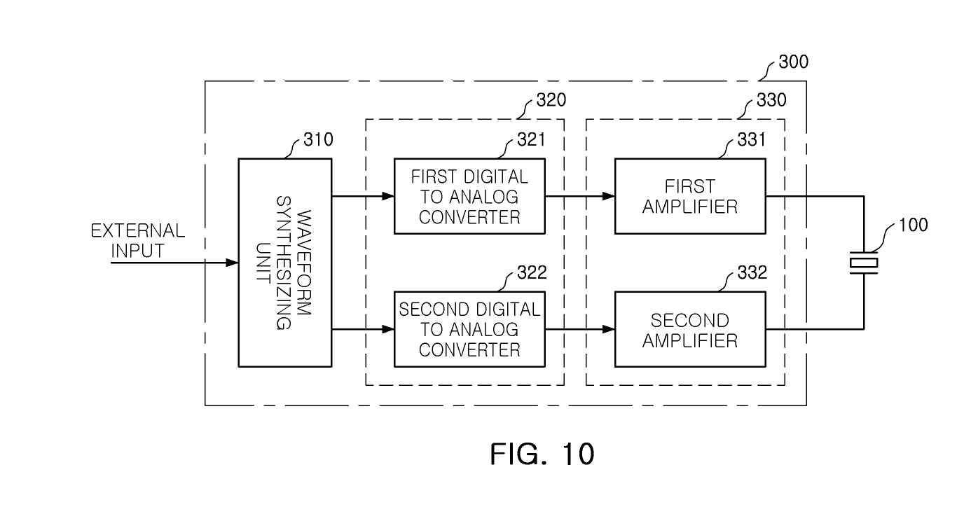

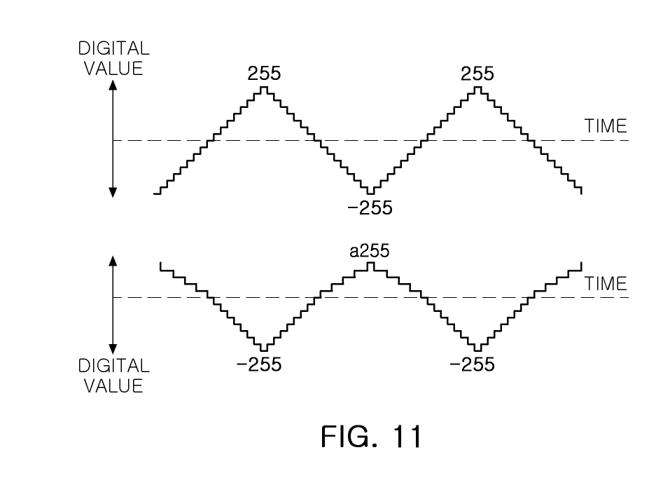

Hereinabove, an exemplary embodiment of the present disclosure in which the asymmetrical driving signal is generated by generating the asymmetrical signal by the digital to analog converting unit 220 has been described. Hereinafter, an exemplary embodiment of the present disclosure in which an asymmetrical driving signal is generated by the waveform synthesizing unit will be described with reference to FIGS. 10 and 11.

FIG. 10 is a block diagram illustrating an apparatus 300 for driving a piezoelectric actuator according to another exemplary embodiment of the present disclosure.

The apparatus 300 for driving the piezoelectric actuator may include a waveform synthesizing unit 310, a digital to analog converting unit 320, and an amplifying unit 330.

The waveform synthesizing unit 310 may output first and second digital signals having a phase difference of 180° from each other. The waveform synthesizing unit 310 may generate the second digital signal as an asymmetrical waveform in response to a control signal input from the outside.

According to an exemplary embodiment of the present disclosure, the waveform synthesizing unit 310 may select and output at least a portion of the digital values included in a preset lookup table. According to another exemplary embodiment of the present disclosure, the waveform synthesizing unit 310 may output the digital value by using a preset function.

FIG. 11 is a graph illustrating an example of a digital signal output from a waveform synthesizing unit of FIG. 10. As illustrated in FIG. 11, although the first and second digital signals output from the waveform synthesizing unit 310 may have the phase difference of 180°, at least a portion of the amplitudes of the first and second digital signals may not equal to each other.

For example, the first digital signal illustrated in an upper portion of FIG. 11 may be the symmetrical signal having a first polarity amplitude and a second polarity amplitude having the same magnitude as each other, and the second digital signal illustrated in a lower portion of FIG. 11 may be an asymmetrical signal having a first polarity amplitude and a second polarity amplitude having a different magnitude.

To this end, the waveform synthesizing unit 310 may generate the first digital signal by using a plurality of digital values included in the preset lookup table and may generate the second digital signal by applying a preset asymmetrical coefficient to at least a portion of the plurality of digital values.

According to an exemplary embodiment of the present disclosure, the waveform synthesizing unit 310 may only apply the asymmetrical coefficient to the digital value corresponding to the first polarity of the second digital signal.

For example, since the first digital signal itself has a symmetrical waveform, the waveform synthesizing unit 310 may generate the first digital signal without performing any processing for data of the lookup table, but may apply the asymmetrical coefficient a to the digital value corresponding to the first polarity (a positive polarity in the example illustrated) of the second digital signal.

The waveform synthesizing unit 310 may provide the first and second digital signals generated described above to the digital to analog converting unit 320.

The digital to analog converting unit 320 may output first and second analog signals corresponding to the first and second digital signals, respectively. In detail, each of the first and second digital to analog converters 321 and 322 may receive the first and second digital signals output from the waveform synthesizing unit 310 and may convert the received first and second digital signals into analog signals. Outputs of the first and second digital to analog converters 321 and 322 may be input to first and second amplifiers 331 and 332, respectively. The first and second amplifiers 331 and 332 may amplify the received first and second analog signals and provide the amplified first and second analog signals to both terminals of the piezoelectric device 100.

Hereinabove, various exemplary embodiments of the apparatus for driving the piezoelectric actuator have been described. Hereinafter, a method of driving a piezoelectric actuator according to an exemplary embodiment of the present disclosure will be described. However, since the method of driving the piezoelectric actuator according to an exemplary embodiment of the present disclosure is performed in the apparatus for driving the piezoelectric actuator described above with reference to FIGS. 5 through 11, a description of content that is the same as or corresponds to the above described description will be omitted.

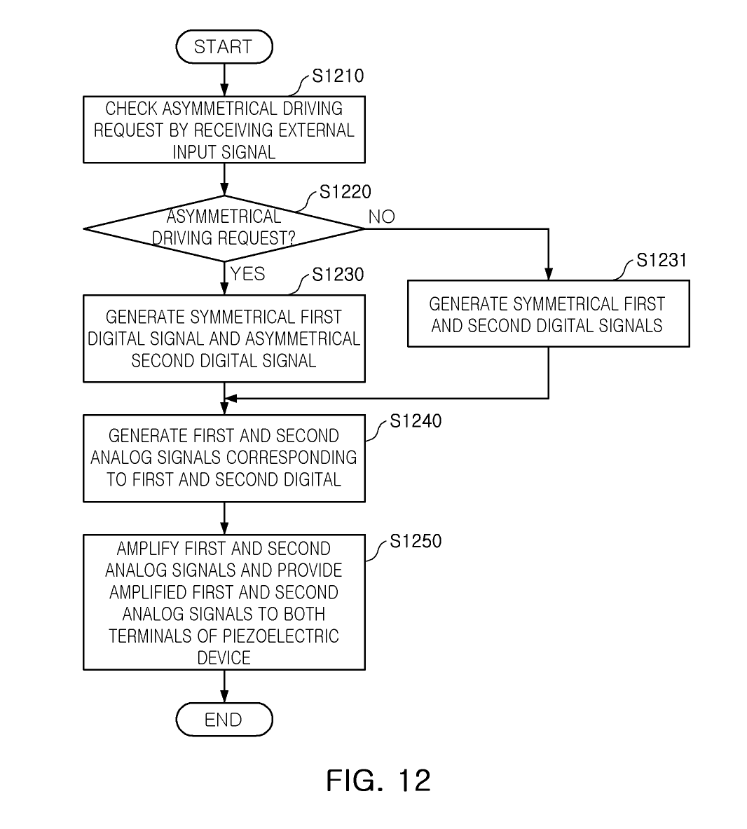

FIG. 12 is a flow chart describing a method of driving a piezoelectric actuator according to an exemplary embodiment of the present disclosure.

Referring to FIG. 12, the apparatus for driving the piezoelectric actuator may receive an external input signal to thereby check a request for asymmetrical driving (S1210).

When the request for the asymmetrical driving is determined (YES of S1220), then the apparatus for driving the piezoelectric actuator may generate a symmetrical first digital signal and an asymmetrical second digital signal (S1230).

Meanwhile, when the request for the asymmetrical driving is not determined (NO of S1220), then the apparatus for driving the piezoelectric actuator may generate symmetrical first and second digital signals (S1231).

The apparatus for driving the piezoelectric actuator may generate first and second analog signals corresponding to the first and second digital signals, respectively (S1240).

In an example of S1230, the apparatus for driving the piezoelectric actuator may generate the first digital signal having the first polarity amplitude and the second polarity amplitude having the same magnitude as each other by using the plurality of digital values included in the preset lookup table. In addition, the apparatus for driving the piezoelectric actuator may generate the second digital signal having the first polarity amplitude and the second polarity amplitude having the different magnitudes from each other by applying the preset asymmetrical coefficient to at least a portion of the plurality of digital values.

In an example of S1230, the apparatus for driving the piezoelectric actuator may only apply the asymmetrical coefficient to the digital value corresponding to the first polarity of the second digital signal.

Next, the apparatus for driving the piezoelectric actuator may amplify the first and second analog signals to thereby respectively provide amplified first and second analog signals to both terminals of the piezoelectric device (S1250).

As set forth above, according to an exemplary embodiment of the present disclosure, the piezoelectric device is driven by selectively using the asymmetrical driving signal and the symmetrical driving signal, whereby dielectric characteristics of the piezoelectric device may be protected and the high output may be provided.

While exemplary embodiments have been illustrated and described above, it will be apparent to those skilled in the art that modifications and variations could be made without departing from the spirit and scope of the present disclosure as defined by the appended claims.

What is claimed is:

1. An apparatus for driving a piezoelectric actuator, the apparatus comprising:
a waveform synthesizing unit outputting a digital signal;
a digital to analog converting unit outputting at least one of a symmetrical waveform or an asymmetrical waveform by converting the digital signal; and
a controlling unit controlling an output of the asymmetrical waveform by controlling an output of the digital to analog converting unit in response to an external input.

2. The apparatus of claim 1, wherein the digital to analog converting unit includes:
a non-weighted digital to analog converter outputting the symmetrical waveform corresponding to the digital signal; and
a weighted digital to analog converter generating the asymmetrical waveform by reflecting a preset asymmetrical coefficient in at least a portion of the digital signal.

3. The apparatus of claim 2, wherein the non-weighted digital to analog converter is a differential digital to analog converter generating a first analog signal corresponding to the digital signal and generating a second analog signal having a phase difference of 180° from the first analog signal.

4. The apparatus of claim 2, wherein a resistor connected to a least significant bit (LSB) of the weighted digital to analog converter has a 1/n value of a resistance value of the non-weighted digital to analog converter, and a resistor connected to a most significant bit (MSB) of the weighted digital to analog converter has a value equal to n-times a resistance value of the non-weighted digital to analog converter, and
wherein n is a natural number.

5. The apparatus of claim 2, wherein the controlling unit includes a multiplexer receiving outputs from the non-weighted digital to analog converter and the weighted digital to analog converter and outputting either of the symmetrical waveform and the asymmetrical waveform.

6. The apparatus of claim 5, wherein the multiplexer provides either of the symmetrical waveform and the asymmetrical waveform to a negative terminal of a piezoelectric device.

7. The apparatus of claim 5, wherein the controlling unit further includes a controller controlling an operation of the multiplexer in response to a control signal input from the outside.

8. The apparatus of claim 7, wherein the controller controls the multiplexer to output the asymmetrical waveform when the control signal corresponds to an output of the asymmetrical driving signal.

9. An apparatus for driving a piezoelectric actuator, the apparatus comprising:
a waveform synthesizing unit outputting first and second digital signals having a phase difference of 180°; and
a digital to analog converting unit outputting first and second analog signals corresponding to the first and second digital signals, respectively,
wherein the waveform synthesizing unit generates the second digital signal as an asymmetrical waveform in response to a control signal input from the outside.

10. The apparatus of claim 9, wherein the asymmetrical waveform is a waveform having a first polarity amplitude and a second polarity amplitude having a different magnitude.

11. The apparatus of claim 10, wherein the waveform synthesizing unit generates the first digital signal by using a plurality of digital values included in a preset lookup table and generates the second digital signal by applying a preset asymmetrical coefficient to at least a portion of the plurality of digital values.

12. The apparatus of claim 11, wherein the waveform synthesizing unit only applies the asymmetrical coefficient to the digital value corresponding to the first polarity of the second digital signal.

13. The apparatus of claim 9, further comprising an amplifying unit amplifying the first and second analog signals to respectively provide the amplified first and second analog signals to both terminals of a piezoelectric device.

14. A method of driving a piezoelectric actuator, the method comprising:
determining a request for asymmetrical driving by receiving an external input signal;
when the request for the asymmetrical driving is determined, generating a symmetrical first digital signal and an asymmetrical second digital signal; and
generating first and second analog signals corresponding to the first and second digital signals, respectively.

15. The method of claim 14, wherein the generating of the first and second digital signals includes:
generating the first digital signal having a first polarity amplitude and a second polarity amplitude having the same magnitude as each other by using a plurality of digital values included in a preset lookup table; and
generating the second digital signal having a first polarity amplitude and a second polarity amplitude having a different magnitude by applying a preset asymmetrical coefficient to at least a portion of the plurality of digital values.

16. The method of claim 15, wherein the generating of the second digital signal only includes applying the asymmetrical coefficient to the digital value corresponding to the first polarity of the second digital signal.

17. The method of claim 14, further comprising amplifying the first and second analog signals to respectively provide the amplified first and second analog signals to both terminals of a piezoelectric device.
